(19) United States
(12) Patent Application Publication
(10) Pub. No.: US 2025/0150056 A1
(43) Pub. Date: May 8, 2025

(54) ACOUSTIC WAVE DEVICE

(71) Applicant: Murata Manufacturing Co., Ltd., Nagaokakyo-shi (JP)

(72) Inventors: Yasumasa TANIGUCHI, Nagaokakyo-shi (JP); Haruki KYOUYA, Nagaokakyo-shi (JP); Daisuke TAMAZAKI, Nagaokakyo-shi (JP)

(21) Appl. No.: 19/013,107

(22) Filed: Jan. 8, 2025

Related U.S. Application Data
(63) Continuation of application No. PCT/JP2023/021583, filed on Jun. 9, 2023.

(30) Foreign Application Priority Data
Jul. 13, 2022 (JP) 2022-112459

(51) Int. Cl. H03H 9/145; C22C 21/12; H03H 9/02; H03H 9/25

(52) U.S. Cl. CPC H03H 9/14541; C22C 21/12; H03H 9/02559; H03H 9/02866; H03H 9/25

(57) ABSTRACT

An acoustic wave device includes a piezoelectric substrate and an interdigital transducer electrode on the piezoelectric substrate. The interdigital transducer electrode includes a close-contact layer on the piezoelectric substrate, a Cu—Al alloy layer on the close-contact layer, and an Al electrode layer on the Cu—Al alloy layer and having a weight-percentage concentration, in % by weight, of Al of greater than about 50% by weight. The Cu—Al alloy layer and the Al electrode layer are epitaxial layers. A thickness of the Cu—Al alloy layer is about 40% or less of a total thickness of the Cu—Al alloy layer and the Al electrode layer.

### CROSS REFERENCE TO RELATED APPLICATIONS

This application claims the benefit of priority to Japanese Patent Application No. 2022-112459 filed on Jul. 13, 2022 and is a Continuation Application of PCT Application No. PCT/JP2023/021583 filed on Jun. 9, 2023. The entire contents of each application are hereby incorporated herein by reference.

### BACKGROUND OF THE INVENTION

### 1. Field of the Invention

The present invention relates to acoustic wave devices.

### 2. Description of the Related Art

To date, acoustic wave devices have been widely used for filters of cellular phones and the like. Japanese Unexamined Patent Application Publication No. 2015-088896 discloses an example of an acoustic wave device. The acoustic wave device described in Japanese Unexamined Patent Application Publication No. 2015-088896 includes an IDT (interdigital transducer) electrode on a piezoelectric substrate. The interdigital transducer electrode includes a multilayer metal film. Specifically, a Ti film, an AlCu film, and a Ti film are stacked in this order. In this regard, the AlCu film is set to be an epitaxial film.

In recent years, further enhancement in the electric power handling capability of the acoustic wave device has been required. However, as an acoustic wave device described in Japanese Unexamined Patent Application Publication No. 2015-088896, when an AlCu alloy is used as the material for forming the interdigital transducer electrode where Cu is added to the Al electrode, electric power handling capability tends to be insufficient. Further, when the Ti film is disposed on the AlCu film, the stress applied to the AlCu film is increased, and there is a concern that the electric power handling capability may deteriorate.

### SUMMARY OF THE INVENTION

Example embodiments of the present invention provide acoustic wave devices each able to decrease the electrical resistance of an electrode finger of the interdigital transducer electrode while improving the electric power handling capability.

An acoustic wave device according to an example embodiment of the present invention includes a piezoelectric substrate and an interdigital transducer electrode on the piezoelectric substrate, wherein the interdigital transducer electrode includes a close-contact layer on the piezoelectric substrate, a Cu—Al alloy layer on the close-contact layer, and an Al electrode layer on the Cu—Al alloy layer and having a weight-percentage concentration, in % by weight, of Al of greater than about 50% by weight, the Cu—Al alloy layer and the Al electrode layer are epitaxial layers, and a thickness of the Cu—Al alloy layer is about 40% or less of a total thickness of the Cu—Al alloy layer and the Al electrode layer.

According to the acoustic wave devices of example embodiments of the present invention, the electrical resistance of an electrode finger of the interdigital transducer electrode is able to be decreased while the electric power handling capability is improved.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view illustrating an acoustic wave device according to an example embodiment of the present invention.

FIG. 2 is a sectional view of the section taken along line I-I in FIG. 1.

FIG. 3 is an enlarged front sectional view illustrating an electrode finger of an interdigital transducer electrode and the vicinity in an example embodiment according to the present invention.

FIG. 4 is a diagram illustrating an example of a boundary between a Cu—Al alloy layer and an Al electrode layer of an electrode finger of the interdigital transducer electrode in an example embodiment according to the present invention.

FIG. 5 is an enlarged front sectional view illustrating an electrode finger of an interdigital transducer electrode and the vicinity in a second comparative example.

FIG. 6 is a diagram illustrating the relationship between the electrical resistance of an electrode finger of an interdigital transducer electrode and the failure electric power in an example embodiment and first to third comparative examples according to the present invention.

FIG. 7 is a front sectional view of an acoustic wave device in a first modified example of an example embodiment according to the present invention.

FIG. 8 is a front sectional view of an acoustic wave device in a second modified example of an example embodiment according to the present invention.

### DETAILED DESCRIPTION OF THE EXAMPLE EMBODIMENTS

The present invention will be clarified by explaining example embodiments according to the present invention with reference to the drawings.

In this regard, each example embodiment described in the present specification is an exemplification, and it is to be noted that configurations described in different example embodiments can be partly replaced or combined with each other.

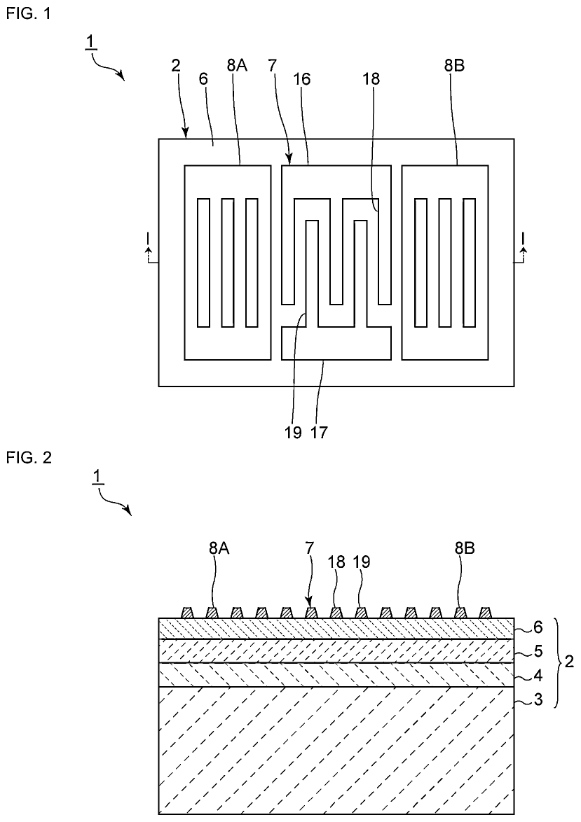

FIG. 1 is a plan view illustrating an acoustic wave device according to an example embodiment of the present invention.

FIG. 2 is a sectional view of the section taken along line I-I in FIG. 1.

As illustrated in FIG. 1 and FIG. 2, an acoustic wave device 1 includes a piezoelectric substrate 2. The piezoelectric substrate 2 is a multilayer substrate including a piezoelectric layer 6. In this regard, the piezoelectric substrate 2 may be a substrate including only a piezoelectric material. That is, it is sufficient that the piezoelectric substrate is a substrate having piezoelectricity. An interdigital transducer electrode 7 is disposed on the piezoelectric substrate 2. More specifically, the interdigital transducer electrode is the 7 disposed on piezoelectric layer 6 in the piezoelectric substrate 2.

As illustrated in FIG. 1, the interdigital transducer electrode 7 includes a first busbar 16, a second busbar 17, a plurality of first electrode fingers 18, and a plurality of second electrode fingers 19. The first busbar 16 and the second busbar 17 are opposed to each other. An end of each of the plurality of first electrode fingers 18 is connected to the first busbar 16. An end of each of the plurality of second electrode fingers 19 is connected to the second busbar 17. The plurality of first electrode fingers 18 and the second electrode fingers 19 are interdigitated with each other. Hereafter the first electrode finger 18 or the second electrode finger 19 is also referred to simply as the electrode finger.

An acoustic wave is excited by applying an alternating current voltage to the interdigital transducer electrode 7. In this regard, when the direction in which the plurality of electrode fingers extend is assumed to be an electrode finger extension direction, the acoustic wave propagation direction is orthogonal or substantially orthogonal to the electrode finger extension direction in the present example embodiment. A pair of reflector 8A and reflector 8B are disposed on the piezoelectric layer 6. The reflector 8A and the reflector 8B are opposed to each other in a direction orthogonal or substantially orthogonal to the electrode finger extension direction with the interdigital transducer electrode 7 interposed therebetween.

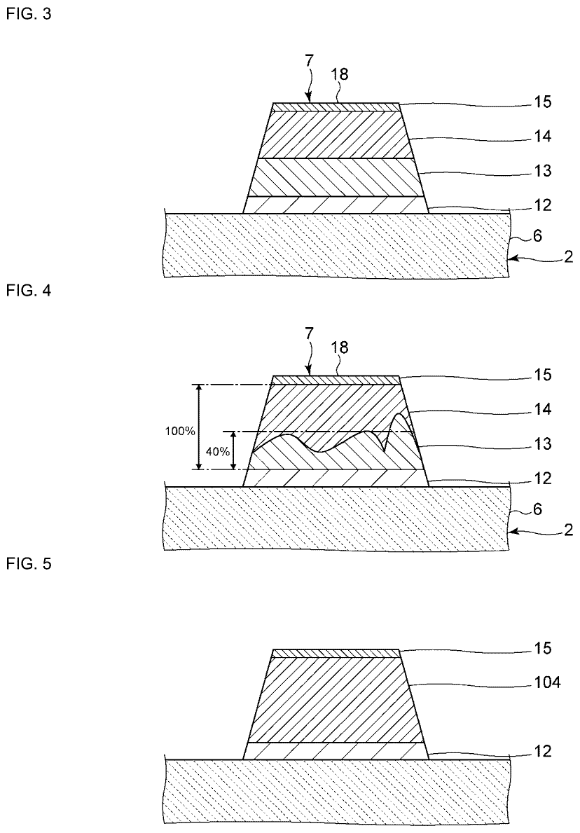

FIG. 3 is an enlarged front sectional view illustrating an electrode finger of the interdigital transducer electrode and the vicinity in the present example embodiment.

The interdigital transducer electrode 7 includes a plurality of electrode layers. Specifically, for example, the interdigital transducer electrode 7 includes a close-contact layer 12, a Cu—Al alloy layer 13, an Al electrode layer 14, and a Ti layer 15. More specifically, the close-contact layer 12 is disposed on the piezoelectric substrate 2. The Cu—Al alloy layer 13 is disposed on the close-contact layer 12. The Al electrode layer 14 is disposed on the Cu—Al alloy layer 13. The Ti layer 15 is disposed on the Al electrode layer 14. However, the Ti layer 15 is not limited to being disposed on the Al electrode layer 14.

The close-contact layer 12, the Cu—Al alloy layer 13, the Al electrode layer 14, and the Ti layer 15 in the interdigital transducer electrode 7 are epitaxially grown electrode layers. In the present specification, an epitaxial layer denotes an electrode layer made of an epitaxially grown oriented film. Further, in the present specification, the epitaxially grown oriented film denotes a polycrystalline film having a twin crystal structure. Whether an electrode layer is an epitaxial layer can be examined by performing pole figure measurement by using an X-ray diffraction method, for example. When the electrode layer has a twin crystal structure, the diffraction pattern has a plurality of symmetry centers. In such an instance, the electrode layer is an epitaxial layer.

The magnitude of the lattice constant of the close-contact layer 12 is the magnitude between the lattice constant of the Cu—Al alloy layer 13 and the lattice constant of a portion provided with the close-contact layer 12 in the piezoelectric substrate 2. In this regard, the portion provided with the close-contact layer 12 in the piezoelectric substrate 2 is the piezoelectric layer 6 in the present example embodiment. Therefore, the magnitude of the lattice constant of the close-contact layer 12 is the magnitude between the lattice constant of the Cu—Al alloy layer 13 and the lattice constant of the piezoelectric layer 6. Accordingly, the close-contact layer 12 may be an epitaxial layer, and in addition, the Cu—Al alloy layer 13 may be an epitaxial layer. In this regard, when the piezoelectric substrate 2 is a substrate including only a piezoelectric material, the magnitude of the lattice constant of the close-contact layer 12 is the magnitude between the lattice constant of the Cu—Al alloy layer 13 and the lattice constant of the piezoelectric substrate 2.

In the present example embodiment, the close-contact layer 12 is, for example, a Ti layer. However, the material of the close-contact layer 12 is not limited to Ti. Regarding the material for the close-contact layer 12, for example, Cr, Ti, or an alloy including Cr or Ti as a primary component can be used. In this regard, the primary component in the present specification denotes a component the proportion of which is more than 50% by weight in the total of the member. The material used for the above-described primary component may be present in a state of any one of a single crystal, a polycrystal, and an amorphous material or a state of a mixture of these.

The Al electrode layer 14 has an Al weight-percentage concentration [% by weight] of, for example, more than about 50% by weight and is an electrode layer mainly including Al. In this regard, in the Al electrode layer 14, Al is, for example, preferably about 80% by weight or more, more preferably about 90% by weight or more, and further preferably about 95% by weight or more. The Al electrode layer 14 having a high Al weight-percentage concentration enables the electrical resistance of the electrode finger of the interdigital transducer electrode 7 to be appropriately decreased. In the Al electrode layer 14 according to the present example embodiment, for example, about 1% by weight of Cu is added to Al. Therefore, for example, in the Al electrode layer 14, Al is about 99% by weight.

In the present example embodiment, for example, the Cu—Al alloy layer 13 and the Al electrode layer 14 are epitaxial layers and the thickness of the Cu—Al alloy layer 13 is about 40% or less of the total thickness of the Cu—Al alloy layer 13 and the Al electrode layer 14. Accordingly, the crystallinity of the Cu—Al alloy layer 13 and the Al electrode layer 14 can be effectively improved. Consequently, the electrical resistance of the electrode finger of the interdigital transducer electrode 7 can be decreased while the electric power handling capability is improved. This advantageous effect will be described below in detail with reference to the detailed configuration of the present example embodiment.

To begin with, the configuration of the present example embodiment will be described in detail. As illustrated in FIG. 2, the piezoelectric substrate 2 includes a support substrate 3, a high-acoustic-velocity film 4 defining and functioning as a high-acoustic-velocity material layer, a low-acoustic-velocity film 5, and the piezoelectric layer 6. The high-acoustic-velocity film 4 is disposed on the support substrate 3. The low-acoustic-velocity film 5 is disposed on the high-acoustic-velocity film 4. The piezoelectric layer 6 is disposed on the low-acoustic-velocity film 5.

The piezoelectric layer 6 in the acoustic wave device 1 is made of, for example, lithium tantalate. In the present specification, some member being made of some material includes the instance in which a very small amount of impurity is contained to such an extent that the electrical characteristics of the acoustic wave device do not significantly deteriorate. However, the material of the piezoelectric layer 6 is not limited to the above, and, for example, lithium niobate, zinc oxide, aluminum nitride, quartz, or PZT (lead zirconate titanate) can be used.

The low-acoustic-velocity film 5 is a relatively low-acoustic-velocity film. More specifically, the acoustic velocity of a bulk wave propagating through the low-acoustic-velocity film 5 is lower than the acoustic velocity of a bulk wave propagating through the piezoelectric layer 6. In the present example embodiment, the low-acoustic-velocity film 5 is made of, for example, silicon oxide. However, the material of the low-acoustic-velocity film 5 is not limited to the above, and, for example, glass, silicon oxide, silicon oxynitride, lithium oxide, tantalum oxide, or a dielectric such as a compound in which fluorine, carbon, or boron is added to silicon oxide or a material including the above-described material as a primary component can be used.

The high-acoustic-velocity material layer is a relatively high-acoustic-velocity layer. The acoustic velocity of a bulk wave propagating through the high-acoustic-velocity material layer is greater than the acoustic velocity of an acoustic wave propagating through the piezoelectric layer 6. In the present example embodiment, the high-acoustic-velocity material layer is a high-acoustic-velocity film 4. The high-acoustic-velocity film 4 is made of, for example, silicon nitride. However, the material of the high-acoustic-velocity material layer is not limited to the above, and, for example, a piezoelectric, such as aluminum nitride, lithium tantalate, lithium niobate, or quartz, ceramics, such as alumina, sapphire, magnesia, silicon nitride, silicon carbide, zirconia, cordierite, mullite, steatite, forsterite, spinel, or sialon, a dielectric, such as aluminum oxide, silicon oxynitride, DLC (diamond-like carbon), or diamond, or a semiconductor, such as silicon, or a material including the above-described material as a primary component can also be used. In this regard, for example, the above-described spinel includes aluminum compounds including oxygen and at least one of Mg, Fe, Zn, Mn, or the like. Examples of the spinel include MgAl₂O₄, FeAl₂O₄, ZnAl₂O₄, or MnAl₂O₄.

In the present example embodiment, the support substrate 3 is made of, for example, silicon. However, the material of the support substrate 3 is not limited to the above, and, for example, a piezoelectric, such as aluminum nitride, lithium tantalate, lithium niobate, or quartz, ceramics, such as alumina, sapphire, magnesia, silicon nitride, silicon carbide, zirconia, cordierite, mullite, steatite, or forsterite, a dielectric, such as diamond or glass, a semiconductor, such as silicon or gallium nitride, or a resin or a material including the above-described material as a primary component can be used.

In the piezoelectric substrate 2 of the acoustic wave device 1, the high-acoustic-velocity film 4 defining and functioning as a high-acoustic-velocity material layer, the low-acoustic-velocity film 5, and the piezoelectric layer 6 are stacked in this order. Accordingly, the energy of an acoustic wave can be effectively confined in the piezoelectric layer 6 side.

In this regard, as described above, in the interdigital transducer electrode 7, the thickness of the Cu—Al alloy layer 13 is, for example, about 40% or less of the total thickness of the Cu—Al alloy layer 13 and the Al electrode layer 14. The thickness relationship in the present specification includes the following relationship. That is, for example, the relationship includes the instance in which the thickness of the Cu—Al alloy layer 13 is more than about 40% of the total thickness of the Cu—Al alloy layer 13 and the Al electrode layer 14 in a section that is a portion of the Cu—Al alloy layer 13 and that is about 20% or less of the bottom area of the Cu—Al alloy layer 13 in plan view. In this regard, “in plan view” in the present specification denotes to view from a position above in FIG. 2. In FIG. 2, for example, the piezoelectric layer 6 side between the support substrate 3 side and the piezoelectric layer 6 is the position above.

The boundary between the Cu—Al alloy layer 13 and the Al electrode layer 14 is actually not a straight line, as illustrated in FIG. 4 as an example. The reason for this is that, during a production process, diffusion between Cu in the Cu—Al alloy layer 13 and Al in the Al electrode layer 14 progresses due to a heat load being added to the interdigital transducer electrode 7. According to this diffusion, the thickness of a portion of the Cu—Al alloy layer 13 may become extremely large relative to the total thickness of the Cu—Al alloy layer 13 and the Al electrode layer 14.

In the example illustrated in FIG. 4, for example, in a section of the Cu—Al alloy layer 13 that is about 80% of the bottom area of the Cu—Al alloy layer 13, the thickness of the Cu—Al alloy layer 13 is about 40% or less of the total thickness of the Cu—Al alloy layer 13 and the Al electrode layer 14. On the other hand, in a section of the Cu—Al alloy layer 13 that is about 20% of the bottom area of the Cu—Al alloy layer 13, the thickness of the Cu—Al alloy layer 13 is more than about 40% of the total thickness of the Cu—Al alloy layer 13 and the Al electrode layer 14. Even in such an instance, for example, the thickness of the Cu—Al alloy layer 13 is assumed to be about 40% or less of the total thickness of the Cu—Al alloy layer 13 and the Al electrode layer 14.

In the present example embodiment, the electrical resistance of the electrode finger of the interdigital transducer electrode 7 can be decreased while the electric power handling capability is improved. This advantageous effect will be described below in detail by comparing the present example embodiment with first to third comparative examples.

The first comparative example differs from the present example embodiment in that the thickness of the Cu—Al alloy layer is more than about 40% of the total thickness of the Cu—Al alloy layer and the Al electrode layer. The second comparative example differs from the present example embodiment in the multilayer configuration of the interdigital transducer electrode. Specifically, as illustrated in FIG. 5, in the second comparative example, the close-contact layer 12, a Cu-added Al layer 104, and the Ti layer 15 are stacked in this order. The third comparative example differs from the present example embodiment in that none of electrode layers in the interdigital transducer electrode are epitaxial layers.

A plurality of acoustic wave devices having the configuration of the present example embodiment and a plurality of acoustic wave devices of the first to third comparative examples were prepared, and an electric power handling test of each acoustic wave device was performed. In the electric power handling test, a predetermined electric power was applied to the acoustic wave device for a predetermined time, and when failure did not occur, the applied electric power was increased by about +0.125 dBm. The failure electric power of the acoustic wave device was determined by repeating this. A plurality of acoustic wave devices were prepared in each of the present example embodiment, the second comparative example, and the third comparative example. The plurality of acoustic wave devices were made to differ from each other in the electrical resistance of the electrode finger of the interdigital transducer electrode. In the first comparative example, the electrical resistance of the electrode finger was a single value. Consequently, the relationship between the electrical resistance of the electrode finger and the failure electric power was determined in each of the present example embodiment and the first to third comparative examples. In this regard, in the present specification, seat resistance [mΩ/□] is used as the electrical resistance of the electrode finger. The design parameter of the acoustic wave device having the configuration of the first example embodiment are as described below.

Support substrate; material silicon, thickness about 125 μm

High-acoustic-velocity film; material SiN, thickness about 300 nm

Low-acoustic-velocity film; material SiO₂, thickness about 300 nm

Piezoelectric layer; material LiTaO₃, thickness about 400 nm

Layer configuration of interdigital transducer electrode; close-contact layer (Ti layer)/Cu—Al alloy layer/Al electrode layer/Ti layer from piezoelectric layer side

Thickness of close-contact layer (Ti layer); about 12 nm

Thickness of Cu—Al alloy layer; about 20 nm or about 40 nm

Atomic ratio of Cu to Al in Cu—Al alloy; Cu:Al=1:1

Total thickness of Cu—Al alloy layer and Al electrode layer; about 100 nm

Material added to Al electrode layer; material Cu, weight-percentage concentration about 1% by weight

Thickness of Ti layer; about 4 nm

In the first comparative example, the thickness of the Cu—Al alloy layer in the interdigital transducer electrode differs from that in the present example embodiment. More specifically, the thickness of the Cu—Al alloy layer in the first comparative example was set to be about 80 nm. In this regard, the total thickness of the Cu—Al alloy layer and the Al electrode layer was about 100 nm.

In the second comparative example, the layer configuration and the thickness of each layer of the interdigital transducer electrode differ from that in the present example embodiment. The design parameters related to the layer configuration and the thickness of each layer of the interdigital transducer electrode in the second comparative example are as described below.

Layer configuration of interdigital transducer electrode; close-contact layer (Ti layer)/Cu-added Al layer/Ti layer from piezoelectric layer side

Thickness of close-contact layer (Ti layer); about 12 nm

Thickness of Cu-added Al layer; about 100 nm

Cu weight-percentage concentration in Cu-added Al layer about 10% by weight, about 20% by weight, or about 30% by weight

Thickness of Ti layer; about 4 nm

In the third comparative example, the range of the thickness of the Cu—Al alloy layer in the interdigital transducer electrode differs from that in the present example embodiment. More specifically, the thickness of the Cu—Al alloy layer in the third comparative example was set to be about 20 nm, about 40 nm, or about 80 nm. In this regard, the total thickness of the Cu—Al alloy layer and the Al electrode layer was about 100 nm.

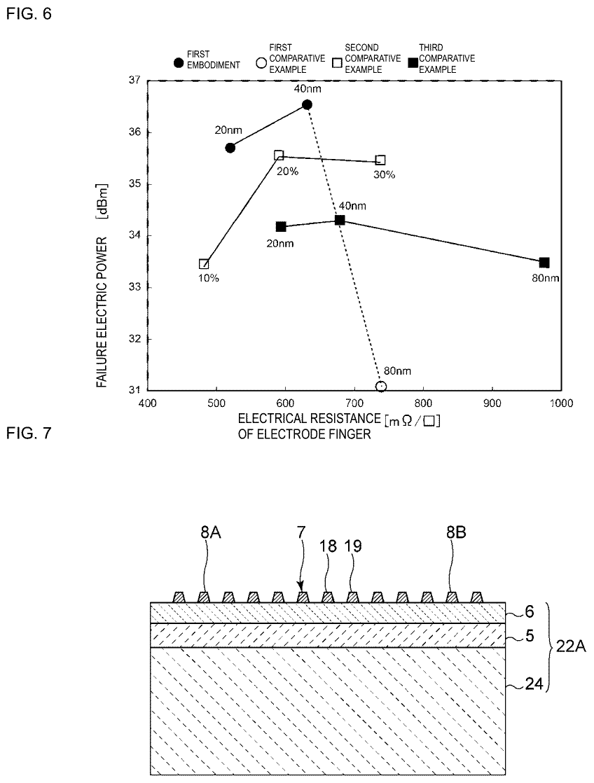

FIG. 6 is a diagram illustrating the relationship between the electrical resistance of the electrode finger of the interdigital transducer electrode and the failure electric power in the present example embodiment and the first to third comparative examples. In FIG. 6, numerical values in the vicinity of plots indicating the results of the present example embodiment, the first comparative example, and the third comparative example indicate the thickness of the Cu—Al alloy layers. In this regard, the total thickness of the Cu—Al alloy layer and the Al electrode layer is set to be about 100 nm. Therefore, for example, when the thickness of the Cu—Al alloy layer is about 40 nm, the thickness of the Cu—Al alloy layer is about 40% of the total thickness of the Cu—Al alloy layer and the Al electrode layer. On the other hand, in FIG. 6, numerical values in the vicinity of plots indicating the results of the second comparative example indicate the Cu weight-percentage concentration in the Cu-added Al layer.

As clearly illustrated in FIG. 6, the failure electric power in the present example embodiment is greater than that in the first to third comparative examples. Therefore, it is clear that the electric power handling capability is improved in the present example embodiment. In addition, it is clear that the electrical resistance of the electrode finger of the interdigital transducer electrode is less than 650 mΩ/□ and is low in the present example embodiment.

In this regard, the first comparative example differs from the present example embodiment only in that the ratio of the thickness of the Cu—Al alloy layer to the thickness of the Cu—Al alloy layer and the Al electrode layer is more than about 40%. In the first comparative example, the electric power handling capability significantly deteriorates compared with the present example embodiment. The reason for this is assumed to be that the crystal state of the Cu—Al alloy layer deteriorates when the thickness of the Cu—Al alloy layer is excessively large. On the other hand, in the present example embodiment, the thickness of the Cu—Al alloy layer is, for example, about 40% or less of the total thickness of the Cu—Al alloy layer and the Al electrode layer. Consequently, the crystal state of the Cu—Al alloy layer can be made favorable, and the electric power handling capability can be enhanced.

In the second comparative example, as illustrated in FIG. 6, the electrical resistance of the electrode finger is low when the amount of Cu added is small in the Cu-added Al layer. However, in such an instance, the electric power handling capability is low. On the other hand, when the amount of Cu added is large in the Cu-added Al layer, the electric power handling capability is improved, but the electrical resistance of the electrode finger is increased. In this regard, for example, when the Cu weight-percentage concentration in the Cu-added Al layer is about 30% by weight, the electrical resistance of the electrode finger is greater than that when the concentration is about 20% by weight. However, the electric power handling capability of the two are at the same level. On the other hand, in the present example embodiment, the Cu—Al alloy layer and the Al electrode layer are stacked, and the ratio of the thickness of the Cu—Al alloy layer to the thickness of the Cu—Al alloy layer and the Al electrode layer is, for example, about 40% of less. Accordingly, the compatibility between the electric power handling capability of the electrode finger being improved and the electrical resistance being decreased can be ensured.

As clearly illustrated in FIG. 6, when the thickness of the Cu—Al alloy layer in the present example embodiment is the same or substantially the same as the thickness of the Cu—Al alloy layer in the comparative example 3, the electrical resistance of the electrode finger in the present example embodiment is lower than the electrical resistance of the electrode finger in the third comparative example. Further, the electric power handling capability in the present example embodiment is greater than the electric power handling capability in the third comparative example. This is due to each electrode layer of the interdigital transducer electrode in the present example embodiment being an epitaxial layer. More specifically, in the present example embodiment, the crystal states of the Cu—Al alloy layer and the Al electrode layer are favorable. Accordingly, when a heat load is applied to the interdigital transducer electrode during the production process, diffusion between Cu in the Cu—Al alloy layer and Al in the Al electrode layer is reduced or prevented. Consequently, the electrical resistance of the electrode finger can be reduced or prevented from increasing. In addition, since the Cu—Al alloy layer and the Al electrode layer have favorable crystallinity, even when stress is applied to the electrode finger by applying a voltage, the electrode finger is not readily damaged. Therefore, the electric power handling capability can be improved.

As illustrated in FIG. 3, in the present example embodiment, the Ti layer 15 is disposed on the Al electrode layer 14. In this regard, the Ti layer 15 is not limited to being disposed. However, it is preferable that the Ti layer 15 is disposed on the Al electrode layer 14. It is more preferable that the Ti layer 15 is an epitaxial layer. Consequently, the electric power handling capability can be effectively improved.

More specifically, stress is applied to the electrode finger due to the Ti layer 15 being disposed. In this regard, the multilayer body of the Cu—Al alloy layer 13 and the Al electrode layer 14 in the present example embodiment has high strength against stress. Therefore, the influence of the above-described stress due to the Ti layer 15 being disposed is small. Meanwhile, an advantageous effect of protecting the Al electrode layer 14 can be obtained by the Ti layer 15 being disposed. Therefore, the electric power handling capability can be effectively improved.

On the other hand, the Cu-added Al layer 104 in the second comparative example illustrated in FIG. 5 does not have high strength against the stress. The reason for this is that the Cu weight-percentage concentration in the Cu-added Al layer 104 is not sufficiently high. In the configuration in which the Ti layer 15 is disposed on the Cu-added Al layer 104, an influence of the stress applied to the Cu-added Al layer 104 is large, and the electric power handling capability tends to be lowered. Therefore, the configuration including the Ti layer 15 is suitable for the present example embodiment of the present invention.

Regarding FIG. 3, in example embodiments of the present invention, there is no particular limitation regarding composition ratio of the alloy in the Cu—Al alloy layer 13. For example, the Cu—Al alloy layer 13 may be made of CuAl₂. However, for example, in the Cu—Al alloy layer 13, it is preferable that the weight-percentage concentration of the Cu—Al alloy in which the atomic ratio of Cu to Al is 1:1 is about 50% by weight or more. Consequently, the electric power handling capability can be further improved.

In this regard, a dielectric film may be disposed on the piezoelectric substrate 2 illustrated in FIG. 2 so as to cover the interdigital transducer electrode 7. In such an instance, since the interdigital transducer electrode 7 is protected by the dielectric film, the interdigital transducer electrode 7 is not readily damaged. Regarding the material for the dielectric film, for example, silicon oxide, silicon nitride, or silicon oxynitride can be used.

In the present example embodiment, the piezoelectric substrate 2 is a multilayer substrate including the piezoelectric layer 6. In the piezoelectric substrate 2, the piezoelectric layer 6 is disposed indirectly on the high-acoustic-velocity film 4 defining and functioning as a high-acoustic-velocity material layer with the low-acoustic-velocity film 5 interposed therebetween. However, the configuration of the piezoelectric substrate 2 is not limited to the above. A first modified example and a second modified example of the present example embodiment which differ from the present example embodiment only in the configuration of the piezoelectric substrate 2 will be described below. In the first modified example and the second modified example, the electrical resistance of the electrode finger of the interdigital transducer electrode 7 can be decreased while the electric power handling capability is improved, as in the present example embodiment. In addition, the energy of an acoustic wave can be effectively confined in the piezoelectric layer 6 side.

In the first modified example illustrated in FIG. 7, the high-acoustic-velocity material layer of a piezoelectric substrate 22A is a high-acoustic-velocity support substrate 24. The low-acoustic-velocity film 5 is disposed on the high-acoustic-velocity support substrate 24. The piezoelectric layer 6 is disposed on the low-acoustic-velocity film 5.

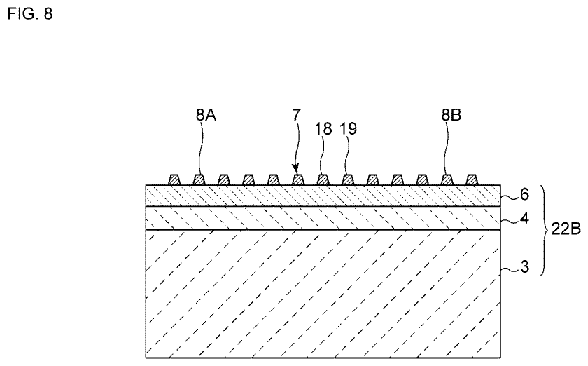

In the second modified example illustrated in FIG. 8, a piezoelectric substrate 22B does not include the low-acoustic-velocity film 5. More specifically, the high-acoustic-velocity film 4 is disposed on the support substrate 3. The piezoelectric layer 6 is disposed directly on the high-acoustic-velocity film 4.

In this regard, the multilayer configuration of the piezoelectric substrate may be a configuration other than the first modified example and the second modified example. For example, the piezoelectric layer may be disposed directly on the high-acoustic-velocity support substrate defining and functioning as the high-acoustic-velocity material layer. In such an instance, the electrical resistance of the electrode finger of the interdigital transducer electrode can be decreased, and the electric power handling capability can be improved, as in the present example embodiment. In addition, the energy of an acoustic wave can be effectively confined in the piezoelectric layer side.

Alternatively, as described above, the piezoelectric substrate may be a substrate including only a piezoelectric material. In such an instance, the electrical resistance of the electrode finger of the interdigital transducer electrode can be decreased, and the electric power handling capability can be improved, as in the present example embodiment.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate; and
an interdigital transducer electrode on the piezoelectric substrate; wherein
the interdigital transducer electrode includes a close-contact layer on the piezoelectric substrate, a Cu—Al alloy layer on the close-contact layer, and an Al electrode layer on the Cu—Al alloy layer and having a weight-percentage concentration, in % by weight, of Al of greater than about 50% by weight;
the Cu—Al alloy layer and the Al electrode layer are epitaxial layers; and
a thickness of the Cu—Al alloy layer is about 40% or less of a total thickness of the Cu—Al alloy layer and the Al electrode layer.

2. The acoustic wave device according to claim 1, wherein the interdigital transducer electrode includes a Ti layer on the Al electrode layer.

3. The acoustic wave device according to claim 2, wherein the Ti layer is an epitaxial layer.

4. The acoustic wave device according to claim 1, wherein a weight-percentage concentration, in % by weight, of Cu—Al alloy in which an atomic ratio of Cu to Al is 1:1, is about 50% by weight or more in the Cu—Al alloy layer.

5. The acoustic wave device according to claim 1, wherein
the piezoelectric substrate includes a high-acoustic-velocity material layer and a piezoelectric layer on the high-acoustic-velocity material layer;
the interdigital transducer electrode is provided on the piezoelectric layer; and
an acoustic velocity of a bulk wave propagating through the high-acoustic-velocity material layer is greater than an acoustic velocity of an acoustic wave propagating through the piezoelectric layer.

6. The acoustic wave device according to claim 5, wherein
a low-acoustic-velocity film is provided between the high-acoustic-velocity material layer and the piezoelectric layer; and
an acoustic velocity of a bulk wave propagating through the low-acoustic-velocity film is lower than an acoustic velocity of a bulk wave propagating through the piezoelectric layer.

7. The acoustic wave device according to claim 5, wherein the high-acoustic-velocity material layer is a high-acoustic-velocity support substrate.

8. The acoustic wave device according to claim 5, wherein
the piezoelectric substrate includes a support substrate; and
the high-acoustic-velocity material layer is a high-acoustic-velocity film provided on the support substrate.

9. The acoustic wave device according to claim 1, wherein the close contact layer includes Ti.

10. The acoustic wave device according to claim 1, wherein the weigh-percentage concentration of Al in the Al electrode layer is about 80% by weight or more.

11. The acoustic wave device according to claim 1, wherein the weigh-percentage concentration of Al in the Al electrode layer is about 90% by weight or more.

12. The acoustic wave device according to claim 1, wherein the weigh-percentage concentration of Al in the Al electrode layer is about 95% by weight or more.

13. The acoustic wave device according to claim 1, wherein the Al electrode layer about 1% by weight of Cu added to the Al.

14. The acoustic wave device according to claim 5, wherein the piezoelectric layer includes lithium tantalate.

15. The acoustic wave device according to claim 6, wherein the low-acoustic-velocity film includes silicon oxide.

16. The acoustic wave device according to claim 5, wherein the high-acoustic-velocity film includes silicon nitride.

17. The acoustic wave device according to claim 8, wherein the support substrate includes silicon.
